(19) United States
(12) Patent Application Publication
(10) Pub. No.: US 2020/0083298 A1
(43) Pub. Date: Mar. 12, 2020

(54) RADIATION DETECTOR

(71) Applicant: Kabushiki Kaisha Toshiba, Minato-ku (JP)

(72) Inventors: Rei Hasegawa, Yokohama (JP); Kohei Nakayama, Kawasaki (JP); Isao Takasu, Setagaya (JP)

(73) Assignee: Kabushiki Kaisha Toshiba, Minato-ku (JP)

(21) Appl. No.: 16/297,774

(22) Filed: Mar. 11, 2019

(30) Foreign Application Priority Data
Sep. 12, 2018 (JP) 2018-170595

(51) Int. Cl. H01L 27/30; H01L 51/44; H01L 51/42; G01T 1/20

(52) U.S. Cl. CPC H01L 27/308; H01L 51/442; G01T 1/2018; H01L 51/447; G01T 1/2002; H01L 51/4253

(57) ABSTRACT

According to one embodiment, a radiation detector includes a first member, a first electrode, a second electrode, and an organic photoelectric conversion layer. The first member converts radiation into light and has a first surface. The first surface includes a first portion and a second portion. The first electrode is provided at the first portion. The second electrode is provided at the second portion. A first intermediate region of the organic photoelectric conversion layer is provided between the first electrode and the second electrode.

### CROSS-REFERENCE TO RELATED APPLICATIONS

This application is based upon and claims the benefit of priority from Japanese Patent Application No. 2018-170595, filed on Sep. 12, 2018; the entire contents of which are incorporated herein by reference.

### FIELD

Embodiments described herein relate generally to a radiation detector.

### BACKGROUND

For example, it is desirable to obtain high detection sensitivity in a radiation detector.

### BRIEF DESCRIPTION OF THE DRAWINGS

FIG. 1 is a schematic cross-sectional view illustrating a radiation detector according to a first embodiment;

FIG. 2 is a schematic perspective view illustrating a portion of the radiation detector according to the first embodiment;

FIG. 3 is a schematic cross-sectional view illustrating a radiation detector according to the first embodiment;

FIG. 4 is a schematic cross-sectional view illustrating a radiation detector according to the first embodiment;

FIG. 5 is a schematic cross-sectional view illustrating a radiation detector according to the first embodiment;

FIG. 6 is a schematic cross-sectional view illustrating a radiation detector according to a second embodiment;

FIG. 7 is a schematic cross-sectional view illustrating a radiation detector according to the second embodiment;

FIG. 8 is a schematic cross-sectional view illustrating a radiation detector according to the second embodiment;

FIG. 9 is a schematic cross-sectional view illustrating a radiation detector according to the second embodiment;

FIG. 10 is a circuit diagram illustrating a portion of the radiation detector; and

FIG. 11 is a schematic cross-sectional view illustrating a portion of the radiation detector.

### DETAILED DESCRIPTION

According to one embodiment, a radiation detector includes a first member, a first electrode, a second electrode, and an organic photoelectric conversion layer. The first member converts radiation into light and has a first surface. The first surface includes a first portion and a second portion. The first electrode is provided at the first portion. The second electrode is provided at the second portion. A first intermediate region of the organic photoelectric conversion layer is provided between the first electrode and the second electrode.

According to another embodiment, a radiation detector includes a first member converting radiation into light, a first electrode, a second electrode, and an organic photoelectric conversion layer contacting the first member. The organic photoelectric conversion layer includes a first region, a second region, and a first intermediate region. The first region is provided between the first electrode and the first member. The second region is provided between the second electrode and the first member. The first intermediate region is provided between the first electrode and the second electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

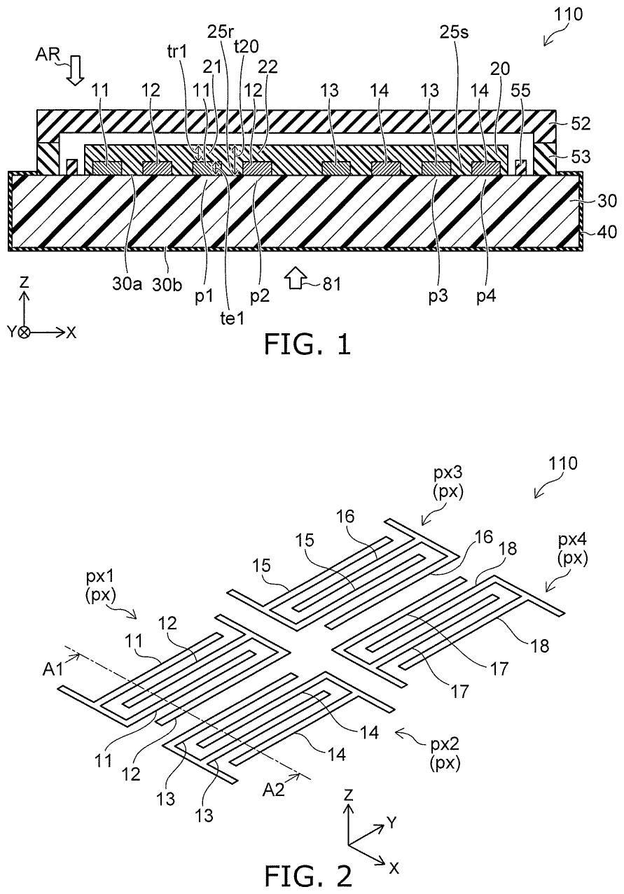

FIG. 1 is a schematic cross-sectional view illustrating a radiation detector according to a first embodiment.

As shown in FIG. 1, the radiation detector 110 according to the embodiment includes a first member 30, a first electrode 11, a second electrode 12, and an organic photoelectric conversion layer 20.

The first member 30 converts radiation 81 into light. The first member 30 is, for example, a scintillator. The radiation 81 includes, for example, β-rays. The light includes, for example, visible light. The light may include, for example, ultraviolet light.

The first member 30 has a first surface 30a. The first surface 30a includes a first portion p1 and a second portion p2.

The first electrode 11 is provided at the first portion p1. The second electrode 12 is provided at the second portion p2.

The organic photoelectric conversion layer 20 includes at least a first intermediate region 25r. The first intermediate region 25r is provided between the first electrode 11 and the second electrode 12.

In the example, the first intermediate region 25r contacts the first member 30.

For example, the radiation 81 is incident on the first member 30. The radiation 81 is converted into light in the first member 30. For example, the light passes between the first electrode 11 and the second electrode 12 and enters the first intermediate region 25r of the organic photoelectric conversion layer 20. For example, a movable charge is generated in the first intermediate region 25r. The amount of the charge changes according to the incident radiation 81. For example, the amount of the charge changes according to the amount of the light generated by the incident radiation 81.

For example, a bias voltage is applied between the first electrode 11 and the second electrode 12. Thereby, a signal that corresponds to the charge is obtained. The signal corresponds to the amount of the incident radiation 81 or the energy of the incident radiation 81. The radiation 81 (e.g., the β-rays) can be detected by the radiation detector 110.

In the embodiment, the light that is generated by the first member 30 passes between the electrodes and can enter the organic photoelectric conversion layer 20 efficiently. The loss of the light can be suppressed. According to the embodiment, a radiation detector can be provided in which the sensitivity can be increased.

The first member 30 includes, for example, an organic substance. The first member 30 is, for example, a plastic scintillator. The first member 30 may include, for example, at least one selected from the group consisting of anthracene, stilbene, polyethylene terephthalate, polystyrene, polyvinyl toluene, polyester, p-terphenyl, tetraphenylbutadiene, and p-di(5-phenyl-2-oxazole)-benzene.

In the embodiment, the absolute value of the difference between the refractive index of the first member 30 and the refractive index of the organic photoelectric conversion layer 20 is 0.2 or less. The absolute value of the difference between the refractive indexes may be 0.1 or less, more preferably.

Because the refractive index difference is small, reflections at the interface between the first member 30 and the organic photoelectric conversion layer 20 can be suppressed. The loss of the light due to reflections can be suppressed. The sensitivity can be increased further.

For example, the refractive index difference becomes large easily in the case where an inorganic scintillator is used. Therefore, the loss due to the reflections at the interface becomes large easily. Because the first member 30 includes an organic substance, the refractive index difference can be small; and the reflections at the interface can be suppressed. The loss of the light due to reflections can be suppressed.

By using the organic photoelectric conversion layer 20 as the photoelectric conversion layer, for example, the target radiation can be detected efficiently. For example, in a reference example in which a material including a heavy element is used as the photoelectric conversion layer, there are cases where direct conversion from the radiation 81 occurs. For example, there are cases where sensitivity to γ-rays occurs in addition to sensitivity to β-rays. By using the organic photoelectric conversion layer 20 as the photoelectric conversion layer, for example, the direct conversion can be suppressed. For example, the target radiation (e.g., the β-rays) can be detected selectively and efficiently by the indirect conversion of the first member 30.

For example, as a first reference example detecting β-rays, a direct conversion radiation detector may be considered in which the organic photoelectric conversion layer is formed on the electrodes. To detect the β-rays, the thickness of the organic photoelectric conversion layer is set to be 200 μm or more. In the case where the organic photoelectric conversion layer is excessively thick, the distance to the electrodes lengthens. There are cases where the charge is annihilated (deactivated) inside the organic photoelectric conversion layer while the charge moves to the electrodes. For example, there are cases where the time of the movement of the charge lengthens; and the output signal that is obtained no longer has a pulse form. In such a case, it may be difficult to discriminate between the output signal and noise. Therefore, the detection efficiency of the first reference example is low.

As a second reference example, an indirect conversion radiation detector may be considered in which a light-transmissive electrode having a flat plate configuration and a scintillator are combined. For example, the refractive index of the light-transmissive electrode is high and is 1.9 or more. On the other hand, the refractive index of the organic photoelectric conversion layer is about 1.5. Because the refractive index difference is large, the light reflects easily at the interface. Light is lost. Therefore, the detection efficiency is low.

The light-transmissive electrode includes an element having a large atomic number such as indium, tin, zinc, etc. Therefore, secondary electrons are generated by the γ-rays due to a photoelectric effect in the light-transmissive electrode. Similarly to the β-rays, the secondary electrons enter the scintillator and generate light. Therefore, the γ-rays also are detected even when it is attempted to transmit the γ-rays and selectively detect the β-rays.

In the embodiment, for example, the refractive index difference can be small. The loss of the light can be suppressed. High detection sensitivity is obtained.

In the embodiment, the radiation 81 is converted into light by the first member 30. Therefore, the organic photoelectric conversion layer 20 may not be thick. For example, the thickness of the organic photoelectric conversion layer 20 may be not less than 0.1 μm and not more than 100 μm. The extraction efficiency of the charge is high. High detection sensitivity is obtained. Because the organic photoelectric conversion layer 20 is moderately thick, the light can be absorbed efficiently. For example, the sensitivity can be higher.

In the embodiment, the electrodes may include aluminum, etc. In such a case, the atomic number of aluminum is relatively small; therefore, the photoelectric effect of γ-rays can be reduced. For example, β-rays or α-rays can be selectively detected.

The organic photoelectric conversion layer 20 may further include a first region 21 and a second region 22 in addition to the first intermediate region 25r. The first electrode 11 is provided between the first region 21 and the first portion p1. The second electrode 12 is provided between the second region 22 and the second portion p2.

For example, the direction from the first member 30 toward the organic photoelectric conversion layer 20 is taken as a Z-axis direction. One direction perpendicular to the Z-axis direction is taken as an X-axis direction. A direction perpendicular to the Z-axis direction and the X-axis direction is taken as a Y-axis direction.

For example, a thickness t20 of the organic photoelectric conversion layer 20 (referring to FIG. 1) may be thicker than a thickness te1 of the first electrode 11. The thickness corresponds to the length along the Z-axis direction.

For example, the thickness of the first electrode 11 along a direction (the Z-axis direction) crossing the first surface 30a is taken as the thickness te1. The thickness of the first region 21 along the crossing direction (the Z-axis direction) is taken as a thickness tr1. The sum of the thickness te1 and the thickness tr1 corresponds to the thickness t20 of the organic photoelectric conversion layer 20. In the embodiment, the sum of the thickness te1 and the thickness tr1 is, for example, not less than 0.1 μm and not more than 100 μm. By such thicknesses, the light can be converted into charge efficiently. The loss of the light can be suppressed. For example, the direct conversion of the radiation 81 can be suppressed.

As shown in FIG. 1, the first member 30 further has a second surface 30b. The first portion p1 is provided between the second surface 30b and the first electrode 11. The second portion p2 is provided between the second surface 30b and the second electrode 12. For example, the first surface 30a is provided between the second surface 30b and the organic photoelectric conversion layer 20. The second surface 30b is the surface on the opposite side of the first surface 30a.

In the example, the radiation 81 enters from the second surface 30b. The radiation 81 enters the first member 30 from the second surface 30b.

As shown in FIG. 1, an optical layer 40 is further provided in the example. The first portion p1 is provided between the optical layer 40 and the first electrode 11. The second portion p2 is provided between the optical layer 40 and the second electrode 12.

For example, the optical layer 40 is provided at the second surface 30b. In the example, the optical layer 40 is provided also at the side surface of the first member 30. The side surface crosses a plane including the first surface 30a.

The optical layer 40 is, for example, a light reflecting layer. For example, the reflectance to the light of the optical layer 40 is higher than the reflectance to the light of the first member 30. The light has a component of the peak wavelength of the light converted from the radiation 81.

By providing the optical layer 40, the light that is generated by the first member 30 can be reflected efficiently toward the organic photoelectric conversion layer 20. The loss of the light can be suppressed further.

The optical layer 40 includes, for example, barium sulfate, etc. The optical layer 40 may include, for example, at least one selected from the group consisting of magnesium carbonate, magnesium oxide, aluminum oxide, a fluoric resin, aluminum, and titanium.

The optical layer 40 transmits the radiation 81.

The first member 30 may function as a base body. The base body supports the electrodes (the first electrode 11, the second electrode 12, etc.) and the organic photoelectric conversion layer 20.

A second member 52 and a bonding layer 53 are further provided in the example. The first electrode 11, the second electrode 12, and the organic photoelectric conversion layer 20 are provided between the second member 52 and the first member 30. The bonding layer 53 bonds the second member 52 and the first member 30.

The second member 52 is, for example, a sealing portion. A space is formed between the first member 30 and the second member 52. The electrodes and the organic photoelectric conversion layer 20 are provided inside the space. The bonding layer 53 airtightly seals the space formed by the second member 52 and the first member 30. For example, contact of the organic photoelectric conversion layer 20 with water, oxygen, etc., can be suppressed.

An absorption layer 55 is further provided in the example. The absorption layer 55 is provided inside the space formed by the first member 30, the second member 52, and the bonding layer 53. For example, the absorption layer 55 absorbs at least one of water or oxygen.

As shown in FIG. 1, a third electrode 13 and a fourth electrode 14 are further provided in the example. The first surface 30a further includes a third portion p3 and a fourth portion p4. The third electrode 13 is provided at the third portion p3. The fourth electrode 14 is provided at the fourth portion p4. The organic photoelectric conversion layer 20 further includes a second intermediate region 25s. The second intermediate region 25s is provided between the third electrode 13 and the fourth electrode 14.

The light that is generated by the first member 30 can be incident on the second intermediate region 25s efficiently. Photoelectric conversion is performed efficiently in the second intermediate region 25s as well. The second intermediate region 25s also can increase the sensitivity.

FIG. 2 is a schematic perspective view illustrating a portion of the radiation detector according to the first embodiment.

FIG. 2 illustrates the electrodes when viewed along arrow AR of FIG. 1. The portions other than the electrodes are not illustrated in FIG. 2. FIG. 1 is a cross-sectional view corresponding to a line A1-A2 cross section of FIG. 2.

The first to eighth electrodes 11 to 18 may be provided as shown in FIG. 2. For example, each of the first to eighth electrodes 11 to 18 may be multiply provided.

For example, the first electrode 11 and the second electrode 12 are included in a first pixel px1. The third electrode 13 and the fourth electrode 14 are included in a second pixel px2.

The fifth electrode 15 and the sixth electrode 16 are included in a third pixel px3. The seventh electrode 17 and the eighth electrode 18 are included in a fourth pixel px4.

For example, the direction from the first pixel px1 toward the second pixel px2 is aligned with the X-axis direction. The direction from the third pixel px3 toward the fourth pixel px4 is aligned with the X-axis direction. The direction from the first pixel px1 toward the third pixel px3 is aligned with the Y-axis direction. The direction from the second pixel px2 toward the fourth pixel px4 is aligned with the Y-axis direction.

Thus, the multiple pixels px may be provided. For example, the multiple pixels px are arranged in a matrix configuration. Multiple electrodes are provided in each of the multiple pixels px.

For example, the first electrode 11 is multiply provided. The second electrode 12 is provided between one of the multiple first electrodes 11 and another one of the multiple first electrodes 11. For example, the second electrode 12 may be multiply provided. For example, the one of the multiple first electrodes 11 recited above is provided between one of the multiple second electrodes 12 and another one of the multiple second electrodes 12.

For example, the multiple first electrodes 11 and the multiple second electrodes 12 form interdigital (e.g., comb teeth) electrodes. Thus, interdigital electrodes may be provided in at least one of the multiple pixels px.

Several examples that relate to the radiation detector according to the embodiment will now be described. Portions that are different from those of the radiation detector 110 will be described.

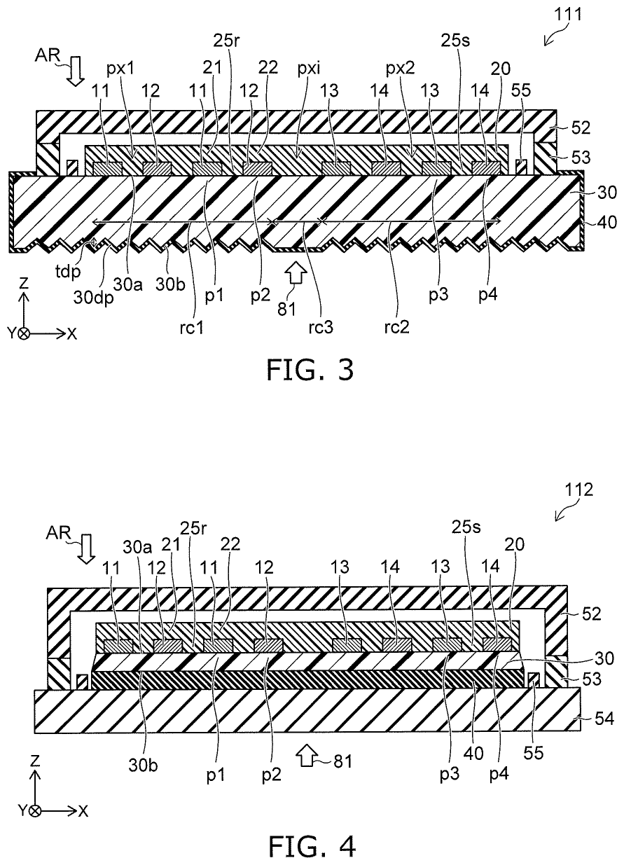

FIG. 3 is a schematic cross-sectional view illustrating a radiation detector according to the first embodiment.

In the radiation detector 111 as shown in FIG. 3, the first member 30 has the first surface 30a and the second surface 30b. In such a case as well, the first portion p1 is provided between the second surface 30b and the first electrode 11. The second portion p2 is provided between the second surface 30b and the second electrode 12. The second surface 30b includes an unevenness 30dp. The optical layer 40 is provided in the example. In the example, the optical layer 40 has a film configuration along the unevenness 30dp.

The light can be reflected efficiently toward the organic photoelectric conversion layer 20 by the unevenness 30dp. A depth tdp of the unevenness 30dp is not less than 20 times and not more than 10000 times the wavelength (e.g., the peak wavelength) of the light generated from the radiation 81.

The unevenness 30dp is selectively provided in the radiation detector 111.

The first to fourth electrodes 11 to 14 are provided as shown in FIG. 3. As described above, the first electrode 11 is provided at the first portion p1 of the first member 30. The second electrode 12 is provided at the second portion p2 of the first member 30. The third electrode 13 is provided at the third portion p3 of the first member 30. The fourth electrode 14 is provided at the fourth portion p4 of the first member 30. The first electrode 11 and the second electrode 12 are included in the first pixel px1 (referring to FIG. 2). The third electrode 13 and the fourth electrode 14 are included in the second pixel px2 (referring to FIG. 2).

As shown in FIG. 3, the second surface 30b of the first member 30 includes a first opposing region rc1, a second opposing region rc2, and a third opposing region rc3. The first opposing region rc1 overlaps the first pixel px1 in the first direction (the Z-axis direction) crossing the first surface 30a. The second opposing region rc2 overlaps the second pixel px2 in the first direction. In the first direction, the third opposing region rc3 overlaps a region pxi between the first pixel px1 and the second pixel px2.

The size of the unevenness 30dp in the first opposing region rc1 is larger than the unevenness in the third opposing region rc3. The size of the unevenness 30dp in the second opposing region rc2 is larger than the unevenness in the third opposing region rc3.

For example, the unevenness 30dp may be provided in the regions corresponding to the pixels; and the surface of the second surface 30b may be flat in the region pxi between the pixels. For example, in the regions corresponding to the pixels, the light is reflected efficiently toward the organic photoelectric conversion layer 20 corresponding to the pixels. In the region pxi between the pixels, the light is reflected efficiently toward the pixels. The loss of the light can be suppressed. The sensitivity can be increased further.

FIG. 4 is a schematic cross-sectional view illustrating a radiation detector according to the first embodiment.

As shown in FIG. 4, the second member 52, the bonding layer 53, and a base body 54 are provided in the radiation detector 112.

The optical layer 40 is provided between the base body 54 and the second member 52. The first member 30 is provided between the optical layer 40 and the second member 52. The electrodes (e.g., the first electrode 11, the second electrode 12, etc.) are provided between the first member 30 and the second member 52.

The bonding layer 53 bonds the base body 54 and the second member 52. The optical layer 40, the first member 30, the electrodes, and the organic photoelectric conversion layer 20 are sealed airtightly in the space formed by the base body 54, the second member 52, and the bonding layer 53.

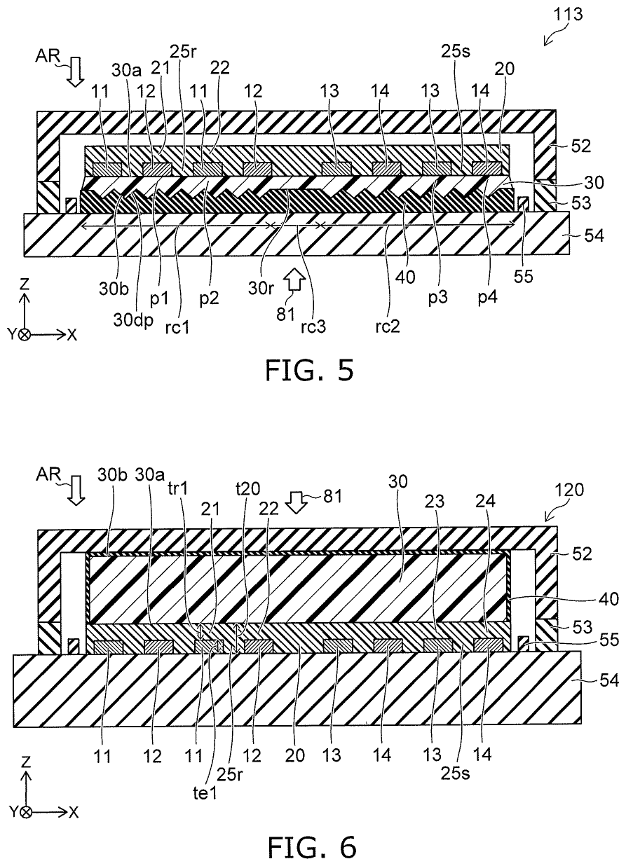

FIG. 5 is a schematic cross-sectional view illustrating a radiation detector according to the first embodiment.

As shown in FIG. 5, the second member 52, the bonding layer 53, and the base body 54 are provided in the radiation detector 113 as well. In the radiation detector 113, the unevenness 30dp is provided in the second surface 30b of the first member 30.

In the example, the size of the unevenness 30dp in the first opposing region rc1 is larger than the unevenness in the third opposing region rc3. The size of the unevenness 30dp in the second opposing region rc2 is larger than the unevenness in the third opposing region rc3. The light is reflected efficiently in the radiation detector 113 as well. The loss of the light can be suppressed. The sensitivity can be increased further.

### Second Embodiment

FIG. 6 is a schematic cross-sectional view illustrating a radiation detector according to a second embodiment.

As shown in FIG. 6, the radiation detector 120 according to the embodiment includes the first member 30, the first electrode 11, the second electrode 12, and the organic photoelectric conversion layer 20.

In the example as well, the first member 30 converts the radiation 81 into light. The organic photoelectric conversion layer 20 contacts the first member 30. The organic photoelectric conversion layer 20 includes the first region 21, the second region 22, and the first intermediate region 25r. The first region 21 is provided between the first electrode 11 and the first member 30. The second region 22 is provided between the second electrode 12 and the first member 30. The first intermediate region 25r is provided between the first electrode 11 and the second electrode 12.

The third electrode 13 and the fourth electrode 14 are further provided in the example. The organic photoelectric conversion layer 20 includes a third region 23, a fourth region 24, and the second intermediate region 25s. The third region 23 is provided between the third electrode 13 and the first member 30. The fourth region 24 is provided between the fourth electrode 14 and the first member 30. The second intermediate region 25s is provided between the third electrode 13 and the fourth electrode 14.

The first member 30 has the first surface 30a and the second surface 30b. The first surface 30a is the surface on the organic photoelectric conversion layer 20 side. The second surface 30b is the surface on the opposite side of the first surface 30a.

For example, the radiation 81 enters the first member 30 from the second surface 30b. Light is generated in the first member 30. The light is incident on the organic photoelectric conversion layer 20 (e.g., the first intermediate region 25r, the second intermediate region 25s, etc.).

Because the organic photoelectric conversion layer 20 contacts the first member 30, the reflection of the light at the interface is suppressed. The light is introduced to the organic photoelectric conversion layer 20 efficiently. For example, the sensitivity can be increased further.

In the example as well, it is favorable for the first member 30 to include an organic substance.

The optical layer 40 is provided in the radiation detector 120 as well. The first member 30 is provided between the optical layer 40 and the organic photoelectric conversion layer 20. In the radiation detector 120, the base body 54 and the second member 52 are bonded by the bonding layer 53. The first member 30, the electrodes, and the organic photoelectric conversion layer 20 are sealed airtightly by the space formed by the bonding.

Several examples of radiation detectors will now be described. In the following description, the portions different from the radiation detector 120 (or the radiation detector 110) will be described.

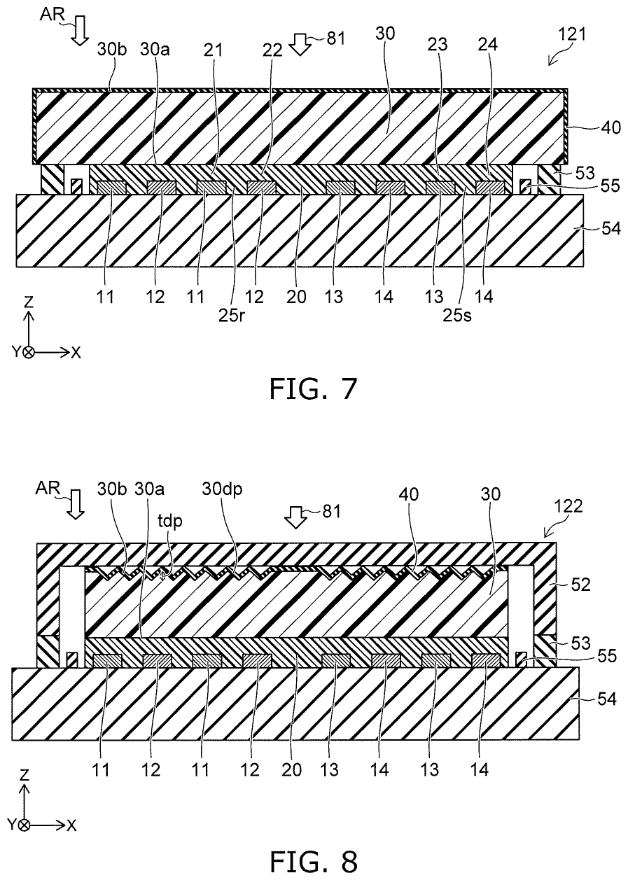

FIG. 7 is a schematic cross-sectional view illustrating a radiation detector according to the second embodiment.

As shown in FIG. 7, the second member 52 is omitted from the radiation detector 121 according to the embodiment. The first member 30 and the base body 54 are bonded by the bonding layer 53. The electrodes and the organic photoelectric conversion layer 20 are sealed airtightly in the space formed by the first member 30, the base body 54, and the bonding layer 53.

FIG. 8 is a schematic cross-sectional view illustrating a radiation detector according to the second embodiment.

As shown in FIG. 8, the unevenness 30dp is provided in the second surface 30b of the first member 30 in the radiation detector 122 according to the embodiment. Otherwise, the configuration of the radiation detector 122 is the same as the configuration of the radiation detector 120. For example, the first surface 30a of the first member 30 is provided between the second surface 30b of the first member 30 and the organic photoelectric conversion layer 20. The second surface 30b includes the unevenness 30dp.

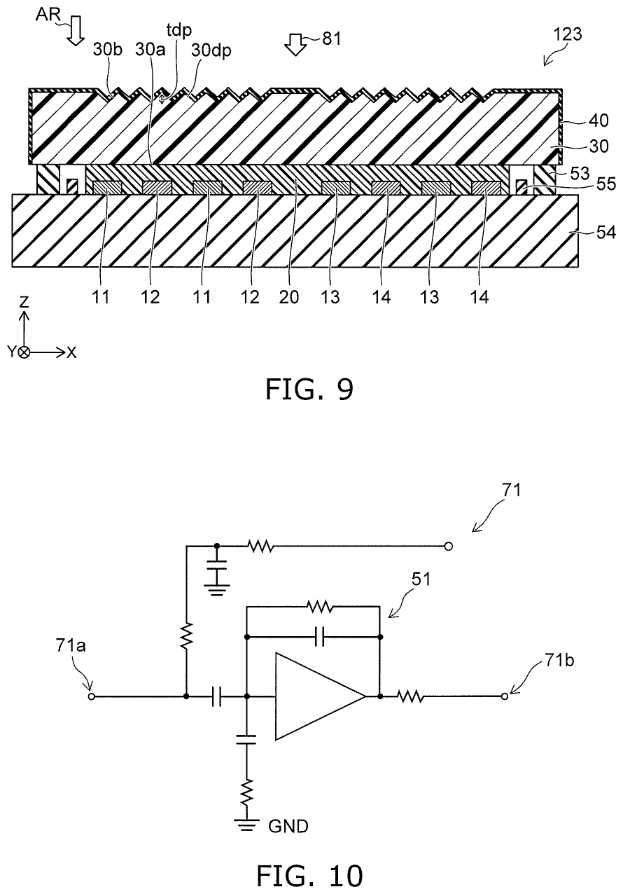

FIG. 9 is a schematic cross-sectional view illustrating a radiation detector according to the second embodiment.

As shown in FIG. 9, the unevenness 30dp is provided in the second surface 30b of the first member 30 of the radiation detector 123 according to the embodiment. Otherwise, the configuration of the radiation detector 123 is the same as the configuration of the radiation detector 121.

The first to fourth electrodes 11 to 14 include, for example, metals. The first to fourth electrodes 11 to 14 may include, for example, the same material. The third electrode 13 may include the same material as the first electrode 11. The fourth electrode 14 may include the same material as the second electrode 12. The first to fourth electrodes 11 to 14 may include, for example, mutually-different materials. The material of the first electrode 11 and the third electrode 13 may be different from the material of the second electrode 12 and the fourth electrode 14. In one example, the first electrode 11 and the third electrode 13 include aluminum; and the second electrode 12 and the fourth electrode 14 include gold. These electrodes include, for example, at least one selected from the group consisting of aluminum, gold, platinum, silver, magnesium, nickel, chrome, and titanium. These electrodes may include ITO (indium tin oxide), PEDOT:PSS (poly(3,4-ethylenedioxythiophene):poly(4-styrenesulfonate)), etc.

In one example, the distance (e.g., the distance along the X-axis direction; referring to FIG. 1) between the first electrode 11 and the second electrode 12 is, for example, not less than 2 μm and not more than 500 μm.

For example, one of the first electrode 11 or the second electrode 12 is connected to a charge amplifier. For example, the other of the first electrode 11 or the second electrode 12 is set to a ground potential. For example, the other of the first electrode 11 or the second electrode 12 may be set to one potential (a reference potential) provided in the radiation detector.

Light is generated when the radiation 81 is incident on the first member 30. The light is converted into a charge (electrons and holes) by the organic photoelectric conversion layer 20. The charge moves to the two electrodes. The charge amplifier outputs a signal corresponding to the radiation 81 incident on the first member 30. The charge amplifier is included in a detection circuit.

The radiation detector according to the embodiment may further include the detection circuit. For example, the detection circuit detects the electrical signal generated between the first electrode 11 and the second electrode 12. The electrical signal is a signal corresponding to the intensity of the radiation 81. The detection circuit outputs a signal corresponding to the electrical signal.

FIG. 10 is a circuit diagram illustrating a portion of the radiation detector.

FIG. 10 shows an example of a detection circuit 71. One of the first electrode 11 or the second electrode 12 is connected to an inputter 71a of the detection circuit 71. The other of the first electrode 11 or the second electrode 12 is connected to a ground GND of the detection circuit 71.

The detection circuit 71 includes, for example, a charge amplifier 51. An output signal that corresponds to the radiation 81 is output from an outputter 71b of the detection circuit 71.

The output of the detection circuit 71 may be supplied to a processor. For example, the processor may shape a waveform using a waveform shaping amplifier (a spectroscopy amplifier) and measure the peak value of the pulse and the number of pulses using a pulse height analyzer (a multichannel analyzer). Or, the processor may shape a waveform using a waveform shaping amplifier, extract the signal that is a preset threshold or more by using a comparator, and measure the number of signals by using a counter circuit.

For example, a signal having the pulse form is output from the charge amplifier 51. For example, the waveform shaping amplifier separates such the signal from the noise component. For example, the waveform shaping amplifier amplifies the signal to match the input range of the pulse height analyzer. For example, the signal that originates in the radiation 81 has a frequency of 1 kHz to 20 kHz. For example, a noise component that has a frequency of less than 1 kHz and a noise component that has a frequency exceeding 20 kHz are separated. For example, the separation is performed by a filter circuit built into the waveform shaping amplifier. The separation may be performed by a filter circuit provided separately. Thereby, the noise component that is included in the signal is reduced. Counting by a pulse method is performed by the charge amplifier 51 and the processor.

An example of the organic photoelectric conversion layer 20 will now be described.

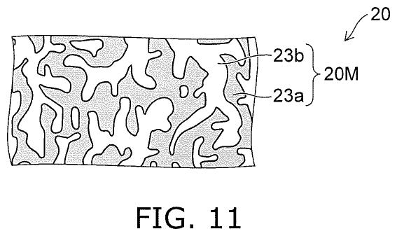

FIG. 11 is a schematic cross-sectional view illustrating a portion of the radiation detector.

FIG. 11 illustrates the organic photoelectric conversion layer 20. The organic photoelectric conversion layer 20 includes, for example, an organic semiconductor region 20M. The organic semiconductor region 20M includes a first compound 23a and a second compound 23b. The first compound 23a includes, for example, polyalkylthiophene. The polyalkylthiophene includes, for example, at least one selected from the group consisting of poly(3-hexylthiophene), poly(3-methylthiophene), poly(3-butylthiophene), poly(3-octylthiophene), poly(3-decylthiophene), and poly(3-dodecylthiophene). The first compound 23a includes, for example, polyalkyl isothionaphthene. The polyalkyl isothionaphthene includes, for example, at least one selected from the group consisting of poly(3-butyl isothionaphthene), poly(3-hexyl isothionaphthene), poly(3-octyl isothionaphthene), and poly(3-decyl isothionaphthene). The second compound 23b includes, for example, fullerene and a fullerene derivative. The second compound 23b includes, for example, at least one selected from the group consisting of [6,6]-phenyl-C61-butyric acid methyl ester (60PCBM), [6,6]-phenyl-C71-butyric acid methyl ester (70PCBM), indene-C60-bis-adduct (60ICBA), dihydronaphthyl-C60-bis-adduct (60NCBA), and dihydronaphthyl-C70-bis-adduct (70NCBA). These regions are mixed. For example, the organic semiconductor region 20M has a bulk heterojunction structure. At least a portion of the organic semiconductor region 20M may be amorphous. For example, the uniformity of the organic semiconductor region 20M becomes high.

In the embodiment, for example, even in a high-γ-ray radiation environment, the other radiation (the α-rays and the β-rays) can be detected with high sensitivity. For example, even in a high-γ-ray radiation environment, the β-rays can be detected with high sensitivity.

The base body 54 includes, for example, a light-transmissive material such as glass, plastic, etc. The second member 52 includes a metal plate, a glass plate, a film plate, etc. The metal plate includes, for example, an aluminum plate having a concave configuration, etc. The bonding layer 53 includes, for example, at least one selected from the group consisting of an acrylic resin and an epoxy resin.

The embodiments include, for example, the following configurations (e.g., technological proposals).

### Configuration 1

A radiation detector, comprising:

a first member converting radiation into light and having a first surface, the first surface including a first portion and a second portion;

a first electrode provided at the first portion;

a second electrode provided at the second portion; and

an organic photoelectric conversion layer,

a first intermediate region of the organic photoelectric conversion layer being provided between the first electrode and the second electrode.

### Configuration 2

The radiation detector according to Configuration 1, wherein the first intermediate region contacts the first member.

### Configuration 3

The radiation detector according to Configuration 1 or 2, wherein the first member includes an organic substance.

### Configuration 4

The radiation detector according to any one of Configurations 1 to 3, wherein

the organic photoelectric conversion layer further includes a first region and a second region,

the first electrode is provided between the first region and the first portion, and

the second electrode is provided between the second region and the second portion.

### Configuration 5

The radiation detector according to any one of Configurations 1 to 4, wherein a sum of a thickness of the first electrode along a direction crossing the first surface and a thickness of the first region along the crossing direction is not less than 0.1 μm and not more than 100 μm.

### Configuration 6

The radiation detector according to any one of

Configurations 1 to 5, wherein the first member further has a second surface,

the first portion is provided between the second surface and the first electrode,

the second portion is provided between the second surface and the second electrode, and

the radiation enters from the second surface.

### Configuration 7

The radiation detector according to any one of Configurations 1 to 5, wherein

the first member further has a second surface,

the first portion is provided between the second surface and the first electrode,

the second portion is provided between the second surface and the second electrode, and

the second surface includes an unevenness.

### Configuration 8

The radiation detector according to Configuration 7, wherein a depth of the unevenness is not less than 20 times and not more than 10000 times a wavelength of the light.

### Configuration 9

The radiation detector according to any one of Configurations 1 to 5, further comprising a third electrode and a fourth electrode,

the first surface further including a third portion and a fourth portion,

the third electrode being provided at the third portion,

the fourth electrode being provided at the fourth portion,

a second intermediate region of the organic photoelectric conversion layer being provided between the third electrode and the fourth electrode,

the first electrode and the second electrode being included in a first pixel,

the third electrode and the fourth electrode being included in a second pixel,

the first member further having a second surface,

the first portion being provided between the second surface and the first electrode,

the second portion being provided between the second surface and the second electrode,

the second surface including a first opposing region, a second opposing region, and a third opposing region,

the first opposing region overlapping the first pixel in a first direction crossing the first surface,

the second opposing region overlapping the second pixel in the first direction,

the third opposing region overlapping, in the first direction, a region between the first pixel and the second pixel,

an unevenness in the first opposing region being larger than an unevenness in the third opposing region.

### Configuration 10

The radiation detector according to any one of Configurations 1 to 9, wherein

a plurality of the first electrodes is provided, and

the second electrode is provided between one of the plurality of first electrodes and another one of the plurality of first electrodes.

### Configuration 11

The radiation detector according to Configuration 10, wherein

a plurality of the second electrodes is provided, and

the one of the plurality of first electrodes is provided between one of the plurality of second electrodes and another one of the plurality of second electrodes.

### Configuration 12

The radiation detector according to any one of Configurations 1 to 11, further comprising an optical layer,

the first portion being provided between the optical layer and the first electrode,

the second portion being provided between the optical layer and the second electrode,

a reflectance to the light of the optical layer being higher than a reflectance to the light of the first member.

### Configuration 13

The radiation detector according to any one of Configurations 1 to 12, further comprising:

a second member; and

a bonding layer,

the first electrode, the second electrode, and the organic photoelectric conversion layer being provided between the second member and the first member,

the bonding layer bonding the second member and the first member.

### Configuration 14

The radiation detector according to Configuration 13, further comprising:

a second member;

a bonding layer; and

a base body,

an optical layer being provided between the base body and the second member,

the first member being provided between the optical layer and the second member,

the first electrode and the second electrode being provided between the first member and the second member.

### Configuration 15

A radiation detector, comprising:

a first member converting radiation into light;

a first electrode;

a second electrode; and

an organic photoelectric conversion layer contacting the first member,

the organic photoelectric conversion layer including a first region, a second region, and a first intermediate region,

the first region being provided between the first electrode and the first member,

the second region being provided between the second electrode and the first member,

the first intermediate region being provided between the first electrode and the second electrode.

### Configuration 16

The radiation detector according to Configuration 15, wherein the first member includes an organic substance.

### Configuration 17

The radiation detector according to Configuration 15 or 16, wherein

the first member has a first surface and a second surface,

the first surface is provided between the second surface and the organic photoelectric conversion layer, and

the second surface includes an unevenness.

### Configuration 18

The radiation detector according to any one of Configurations 1 to 17, wherein an absolute value of a difference between a refractive index of the first member and a refractive index of the organic photoelectric conversion layer is 0.2 or less.

### Configuration 19

The radiation detector according to any one of Configurations 1 to 18, wherein the radiation includes β-rays.

### Configuration 20

The radiation detector according to any one of Configurations 1 to 19, further comprising a detection circuit detecting an electrical signal corresponding to an intensity of the radiation, the electrical signal being generated between the first electrode and the second electrode.

According to the embodiments, a radiation detector can be provided in which the sensitivity can be increased.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in radiation detectors such as members, electrodes, organic photoelectric conversion layers, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all radiation detectors practicable by an appropriate design modification by one skilled in the art based on the radiation detectors described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A radiation detector, comprising:
a first member converting radiation into light and having a first surface, the first surface including a first portion and a second portion;
a first electrode provided at the first portion;
a second electrode provided at the second portion; and
an organic photoelectric conversion layer,
a first intermediate region of the organic photoelectric conversion layer being provided between the first electrode and the second electrode.

2. The detector according to claim 1, wherein the first intermediate region contacts the first member.

3. The detector according to claim 1, wherein the first member includes an organic substance.

4. The detector according to claim 1, wherein
the organic photoelectric conversion layer further includes a first region and a second region,
the first electrode is provided between the first region and the first portion, and
the second electrode is provided between the second region and the second portion.

5. The detector according to claim 1, wherein a sum of a thickness of the first electrode along a direction crossing the first surface and a thickness of the first region along the crossing direction is not less than 0.1 μm and not more than 100 μm.

6. The detector according to claim 1, wherein
the first member further has a second surface,
the first portion is provided between the second surface and the first electrode,
the second portion is provided between the second surface and the second electrode, and
the radiation enters from the second surface.

7. The detector according to claim 1, wherein
the first member further has a second surface,
the first portion is provided between the second surface and the first electrode,
the second portion is provided between the second surface and the second electrode, and
the second surface includes an unevenness.

8. The detector according to claim 7, wherein a depth of the unevenness is not less than 20 times and not more than 10000 times a wavelength of the light.

9. The detector according to claim 1, further comprising a third electrode and a fourth electrode,
the first surface further including a third portion and a fourth portion,
the third electrode being provided at the third portion,
the fourth electrode being provided at the fourth portion,
a second intermediate region of the organic photoelectric conversion layer being provided between the third electrode and the fourth electrode,
the first electrode and the second electrode being included in a first pixel,
the third electrode and the fourth electrode being included in a second pixel,
the first member further having a second surface,
the first portion being provided between the second surface and the first electrode,
the second portion being provided between the second surface and the second electrode,
the second surface including a first opposing region, a second opposing region, and a third opposing region,
the first opposing region overlapping the first pixel in a first direction crossing the first surface,
the second opposing region overlapping the second pixel in the first direction,
the third opposing region overlapping, in the first direction, a region between the first pixel and the second pixel,
an unevenness in the first opposing region being larger than an unevenness in the third opposing region.

10. The detector according to claim 1, wherein
a plurality of the first electrodes is provided, and
the second electrode is provided between one of the plurality of first electrodes and another one of the plurality of first electrodes.

11. The detector according to claim 10, wherein
a plurality of the second electrodes is provided, and
the one of the plurality of first electrodes is provided between one of the plurality of second electrodes and another one of the plurality of second electrodes.

12. The detector according to claim 1, further comprising an optical layer,
the first portion being provided between the optical layer and the first electrode,
the second portion being provided between the optical layer and the second electrode,
a reflectance to the light of the optical layer being higher than a reflectance to the light of the first member.

13. The detector according to claim 1, further comprising:
a second member; and
a bonding layer,
the first electrode, the second electrode, and the organic photoelectric conversion layer being provided between the second member and the first member,
the bonding layer bonding the second member and the first member.

14. The detector according to claim 13, further comprising:
a second member;
a bonding layer; and
a base body,
an optical layer being provided between the base body and the second member,
the first member being provided between the optical layer and the second member,
the first electrode and the second electrode being provided between the first member and the second member.

15. A radiation detector, comprising:
a first member converting radiation into light;
a first electrode;
a second electrode; and
an organic photoelectric conversion layer contacting the first member,
the organic photoelectric conversion layer including a first region, a second region, and a first intermediate region,
the first region being provided between the first electrode and the first member,
the second region being provided between the second electrode and the first member,
the first intermediate region being provided between the first electrode and the second electrode.

16. The detector according to claim 15, wherein the first member includes an organic substance.

17. The detector according to claim 15, wherein
the first member has a first surface and a second surface,
the first surface is provided between the second surface and the organic photoelectric conversion layer, and
the second surface includes an unevenness.

18. The detector according to claim 1, wherein an absolute value of a difference between a refractive index of the first member and a refractive index of the organic photoelectric conversion layer is 0.2 or less.

19. The detector according to claim 1, wherein the radiation includes β-rays.

20. The detector according to claim 1, further comprising a detection circuit detecting an electrical signal corresponding to an intensity of the radiation, the electrical signal being generated between the first electrode and the second electrode.
